(19) United States
(12) Patent Application Publication
(10) Pub. No.: US 2026/0051872 A1
(43) Pub. Date: Feb. 19, 2026

(54) DUAL RING MICROELECTROMECHANICAL SYSTEMS INTEGRATION FOR ANALOG TUNABILITY IN RECONFIGURABLE INTELLIGENT SURFACES

(71) Applicant: Dell Products L.P., Round Rock, TX (US)

(72) Inventors: Tejinder Singh, Manotick (CA); Navjot Kaur Khaira, Manotick (CA)

(21) Appl. No.: 18/808,987

(22) Filed: Aug. 19, 2024

(51) Int. Cl. H03H 9/24; H03H 9/125

(52) U.S. Cl. CPC H03H 9/2405; H03H 9/125

(57) ABSTRACT

The technology described herein is directed towards a reconfigurable intelligent surface (RIS) based on microelectromechanical systems (MEMS) technology, in which metallic MEMS micro-actuators are integrated into unit cells of the RIS. Dual ring-shaped metallic cantilevers, resulting from unit cell fabrication, operate as electrothermal actuators in the unit cell's resonating pattern. A controlled voltage can be separately applied to each ring-shaped cantilever, deforming (bending up) each ring at its non-anchored (free) portion from its generally flat non-actuated state via joule heating. The amount of vertical displacement of the free portion of each ring when voltage is applied separately changes the structure of the unit cell's geometry based on each amount of applied voltage, whereby analog-like tuning of the unit cell's characteristics (including phase shift) is obtained. When combined with the voltage-controlled phase shifts of other unit cells of the RIS, beamforming of a reflected incoming electromagnetic wave is facilitated.

### BACKGROUND

Reconfigurable intelligent surfaces (alternatively referred to metasurfaces) are manmade thin reflective or refractive surfaces with electronically adjustable properties that can manipulate electromagnetic waves. A reconfigurable intelligent surface is generally characterized by having a two-dimensional planar array of sub-wavelength structures, known as unit cells, whose characteristics are primarily dictated by the geometry of these structures. These elements are capable of altering the phase shift of the reflected signals, through active elements such as PIN diodes or varactors that tune electromagnetic responses, whereby through precise adjustment of these phase shifts, sophisticated reflect beamforming can be executed.

### BRIEF DESCRIPTION OF THE DRAWINGS

The technology described herein is illustrated by way of example and not limited in the accompanying figures in which like reference numerals indicate similar elements and in which:

FIG. 1 is a three-dimensional perspective view representation of an example unit cell of a reconfigurable intelligent surface for redirecting an incoming electromagnetic signal based on microelectromechanical systems (MEMS)-based phase control of dual ring-type cantilevers, in accordance with various example embodiments and implementations of the subject disclosure.

FIG. 2 is a top view representation of the example unit cell of FIG. 1, in accordance with various example embodiments and implementations of the subject disclosure.

FIGS. 3A and 3B are side view representations of an example MEMS-based actuator highlighting fabrication before and after removal of a sacrificial layer, respectively, in accordance with various example embodiments and implementations of the subject disclosure.

FIG. 3C is a side view representation of an example MEMS-based actuator showing an example in which one cantilever (of two cantilevers) is shown as bent upwards as a result of joule heating, in accordance with various example embodiments and implementations of the subject disclosure.

FIG. 4A is a three-dimensional perspective view representation of an example MEMS-based unit cell showing a movable inner ring resonator's (cantilever's) vertical displacement when subject to joule heating (non-zero applied voltage), in accordance with various example embodiments and implementations of the subject disclosure.

FIG. 4B is a three-dimensional perspective view representation of an example MEMS-based unit cell showing a movable outer ring resonator's (cantilever's) vertical displacement when subject to joule heating (non-zero applied voltage), in accordance with various example embodiments and implementations of the subject disclosure.

FIG. 5A is a three-dimensional perspective view representation of an example MEMS-based unit cell showing a resonator's movable inner and outer ring (cantilevers') vertical displacements when both are subject to joule heating (non-zero applied voltage), in accordance with various example embodiments and implementations of the subject disclosure.

FIG. 5B is a top-view representation of the voltage distribution when voltages are applied to the dual-ring cantilevers, in accordance with various example embodiments and implementations of the subject disclosure.

FIG. 6A is a three-dimensional perspective view representation of an example MEMS-based unit cell showing temperatures within a movable inner and outer ring when both are subject to joule heating (non-zero applied voltage), in accordance with various example embodiments and implementations of the subject disclosure.

FIG. 6B is a top-view representation of the temperatures in the rings of FIG. 6A, in accordance with various example embodiments and implementations of the subject disclosure.

FIGS. 7A-7D are side view representations of example dual-ring cantilever corresponding to various zero voltage non-actuated states, and non-zero voltage actuated states, in accordance with various example embodiments and implementations of the subject disclosure.

FIG. 8 is an example three-dimensional perspective view representation of meshing a dual cantilever MEMS-based unit cell structure for finite element analysis, in accordance with various example embodiments and implementations of the subject disclosure.

FIG. 9 is an example graphical representation of displacement of one ring of a unit cell at 40 GHz for varying voltages from 0 to 20 V with 1 V step size, in accordance with various example embodiments and implementations of the subject disclosure.

FIG. 10A is an example graphical representation of magnitude of a unit cell at 40 GHz for varying voltages from 0 to 20 V, in accordance with various example embodiments and implementations of the subject disclosure.

FIG. 10B is an example graphical representation of reflection phase of a unit cell at 40 GHz for varying voltage from 0 V to 20 V at the anchors with 4 V step size, in accordance with various example embodiments and implementations of the subject disclosure.

FIG. 11 is a three-dimensional representation of an example 8×8 array of unit cells forming a reconfigurable intelligent surface, along with an enlarged unit cell, in accordance with various example embodiments and implementations of the subject disclosure.

FIGS. 12A and 12B are example representations of beam steering of a reflected incoming electromagnetic wave in which reflected beam can be steered in desired target directions based on the voltages applied to the cantilevers/middle rings of the unit cells.

FIGS. 13 and 14 comprise a flow diagram showing example operations related to controlling first and second bias voltage applied to first and second moveable elements, respectively, of a microelectromechanical systems-based resonating pattern to change a phase shift of a unit cell of a reconfigurable intelligent surface, in accordance with various example embodiments and implementations of the subject disclosure.

### DETAILED DESCRIPTION

The technology described herein is generally directed towards a reconfigurable intelligent surface of unit cells that includes dynamic control of the unit cells facilitated through the structural reconfiguration of unit-cell geometry using microelectromechanical systems (MEMS). In general, MEMS are miniature integrated devices or systems that combine electrical and mechanical components, which range in size from a few micrometers to millimeters, enabling technology to operate at a scale previously unachievable. Fabricated through microfabrication techniques akin to those in the semiconductor industry, MEMS devices offer mass production capabilities with high reliability and consistency at a relatively low cost. These versatile systems find extensive applications across various domains including automotive, consumer electronics, healthcare, and telecommunications. With reconfigurable intelligent surfaces falling within the millimeter or microscale range for millimeter-wave frequencies, MEMS integration as described herein is a very suitable platform.

In general, the technology described herein achieves unit cell reconfigurability in using electrothermally actuated MEMS. As will be understood, the technology involves multicycle operation of electrothermally reconfigurable MEMS, e.g., using a dual ring cantilever-type structure composed of a material (e.g., aluminum) that curves as a result of joule heating when current flows through the material. The temperature-driven characteristics of the constituent material results in an overall out-of-plane deformation of one or both of the rings, in an amount corresponding to the respective amounts of joule heating applied to the respective rings. This structural adaptation is highly effective in finely adjusting the individual electromagnetic properties of a reconfigurable intelligent surface's unit cells in real-time.

Structural reconfiguration of unit cell geometry using MEMS technology, by integrating MEMS actuators with unit cells of a reconfigurable intelligent surface as described herein, enables dynamic reshaping of unit cell geometries, facilitating tunable millimeter-wave response. The micro/millimeter scale dimensions of the MEMS actuator as described herein complement the size of unit cells at millimeter wave frequencies. This technology capitalizes on the structural displacement induced in the actuators under DC voltage bias, effectively altering the electromagnetic response of the unit cell.

The technology described herein achieves continuous tunability by adjusting the respective vertical displacement distances of respective non-anchored portions of the respective movable rings within a unit cell's metallic resonating pattern. Unlike approaches based on PIN diodes/varactors, which are limited to binary (1-bit) states in PIN diodes and six capacitance states in varactors, the utilization of MEMS out-of-plane actuators as described herein enables seamless, uninterrupted analog-type tuning over a large range. Electrothermal actuation provides significant displacement, thereby extending the tuning range. Through analog tuning of phase from individual unit cell, precise control over a reflected beam from a reconfigurable intelligent surface's unit cell array is achieved, enhancing adaptability and functionality across various applications.

The monolithic integration of MEMS actuators within reconfigurable intelligent surfaces as described herein provides significant advantages over traditional methods employing PIN diodes/varactors. Unlike these discrete components that need to be soldered onto the surface of the RIS, MEMS actuators can be seamlessly incorporated into the fabrication process, ensuring a more streamlined and efficient assembly. Moreover, the integration of MEMS within a reconfigurable intelligent surface eliminates the need for complex biasing and extensive wiring, simplifying the overall design and reducing potential points of failure. Additionally, MEMS integration with a reconfigurable intelligent surface offers compatibility with CMOS technology, further enhancing the feasibility and scalability of such systems.

It should be understood that any of the examples and/or descriptions herein are non-limiting. Thus, any of the embodiments, example embodiments, concepts, structures, functionalities or examples described herein are non-limiting, and the technology may be used in various ways that provide benefits and advantages in communications and computing in general.

Reference throughout this specification to “one embodiment,” “an embodiment,” “one implementation,” “an implementation,” etc. means that a particular feature, structure, characteristic and/or attribute described in connection with the embodiment/implementation can be included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, characteristics and/or attributes may be combined in any suitable manner in one or more embodiments/implementations. Repetitive description of like elements employed in respective embodiments may be omitted for sake of brevity.

The detailed description is merely illustrative and is not intended to limit embodiments and/or application or uses of embodiments. Furthermore, there is no intention to be bound by any expressed or implied information presented in the preceding sections, or in the Detailed Description section. Further, it is to be understood that the present disclosure will be described in terms of a given illustrative architecture; however, other architectures, structures, materials and process features, and steps can be varied within the scope of the present disclosure.

It also should be noted that terms used herein, such as “optimize,” “optimization,” “optimal,” “optimally” and the like only represent objectives to move towards a more optimal state, rather than necessarily obtaining ideal results. Similarly, “maximize” means moving towards a maximal state (e.g., up to some processing capacity limit), not necessarily achieving such a state, and so on.

It will also be understood that when an element such as a layer, region or substrate is referred to as being “on” or “over” “atop” “above” “beneath” “below” and so forth with respect to another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

The following detailed description is merely illustrative and is not intended to limit embodiments and/or application or uses of embodiments. Furthermore, there is no intention to be bound by any expressed or implied information presented in the preceding sections, or in the Detailed Description section.

One or more example embodiments are now described with reference to the drawings, in which example components, graphs and/or operations are shown, and in which like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details, and that the subject disclosure may be embodied in many different forms and should not be construed as limited to the examples set forth herein.

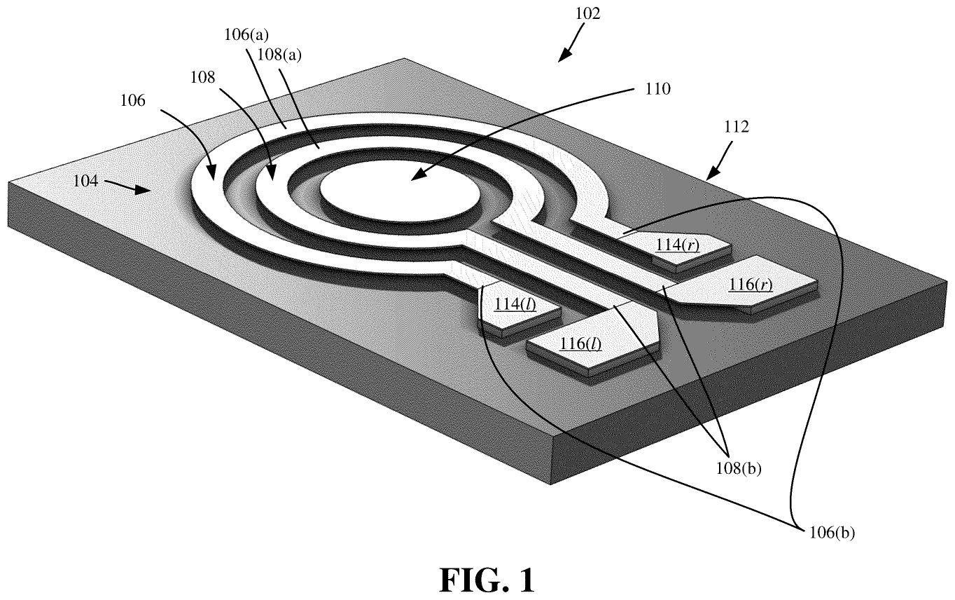

FIG. 1 is a three-dimensional (3D) perspective representation of an example unit cell 102 of a type that redirects (reflects or refracts) incoming electromagnetic signals. The unit cell 102, in conjunction with other unit cells, forms a reconfigurable intelligent surface. In general, the reflective surface is formed by a two-dimensional periodic array of such unit cells.

In one implementation, the unit cell 102 includes a resonating pattern 104 of metallic elements, such as including a generally ring-shaped resonator pattern configured to resonate when the incoming electromagnetic (EM)/radio frequency (RF) wave is impinging on the unit cell 102, such as an RF signal near or within the millimeter wavelength, e.g., (above 25 gigahertz) or higher. In general, the metallic resonating pattern is designed to resonate at a frequency that corresponds to the frequency of the incoming signal. As set forth herein, a unit cell 102 can have a resonating pattern 104 of any suitable shape (e.g., square, rectangular, concentric ring-shape, coupled circles and so on) that resonates at a corresponding frequency of the incoming signal, and is thus not limited to any particular pattern. Note that in the examples herein, a unit cell 102 is designed for operation at 37-45 GHz; notwithstanding, the technology described herein can be easily extended to other frequency ranges.

In general, the metallic resonating pattern 104 is designed for operation at a desired resonance frequency that corresponds to the frequency of the incoming signal. More particularly, FIG. 1 shows a unit cell 102 for a reconfigurable millimeter wave (mmWave) reflective surface that is based on using a microelectromechanical systems (MEMS) actuator to achieve the dynamic tuning of the reflection phase. In one example implementation described herein, the unit cell structure 102 has the metallic pattern 104 generally shaped like a bullseye, which includes metallic concentric circular (e.g., penannular) rings, including an outer ring 106 and an inner ring 108 surrounding an inner (center) disk 110 fixed to a substrate 112. The outer ring 106 and the inner ring 108 are each made from a bendable material as described herein.

As described herein, both the outer ring 106 and the inner ring 108 are bendable (movable) in a vertical direction at respective portions 106(a) and 108(a) thereof, and fixed at the opposite (extended) portions 106(b) and 108(b), respectively. The fixed outer ring portion 106(b) is fixed by two outer anchors 114(l) and 114(r) to opposite extended left and right sides of the penannular inner ring 106, whereby the outer ring 106 is a cantilever. Similarly, the fixed inner ring portion 108(b) is fixed by two inner left and right anchors 116(l) and 116(r) to opposite extended left and right sides of the penannular inner ring 108, whereby the inner ring 108 is also a cantilever.

These anchors 114(l), 114(r), 116(l) and 116(r) can incorporate, or can be coupled to, respective electrical contact pairs for applying respective bias voltages (or currents) across the respective contacts, resulting in independent joule heating of the outer ring 106 and the inner ring 108 that, in one implementation, selectively bends the outer ring 106 and/or the inner ring 108 upward from a substantially parallel (to the substrate 112) state away from the substrate 112 in respective amounts corresponding to the respective applied voltages. Note that although not explicitly shown in FIG. 1, the electrical contacts can be beneath the substrate 112, and, for example, extend through a ground plane of the reconfigurable intelligent surface by vias, one of which is electrically insulated from the ground plane (e.g., beneath the substrate, not explicitly shown) to carry one of the positive voltages to one side of the outer ring 106, and another of the positive voltages to one side of the inner ring 108; the other vias couple the respective opposite sides of the outer ring 106 and the inner ring 108 to ground/the ground plane.

In general, MEMS technology has enabled a wide variety of micro-actuators with varied performance in terms of deformation range, reconfiguration direction, response time, power consumption, case of integration and CMOS compatibility. These micro-actuators, including cantilevers, beams, diaphragms, and frames, enable mechanical deformation under external stimuli, hence the designation of ‘micro-actuators’.

Described herein is a micro-actuator based on the cantilever actuator, characterized by its thin, rigid structure anchored at one end with free movement at the other end. During the fabrication process, a sacrificial layer is often used to facilitate the creation of free-standing structures like cantilevers. These sacrificial layers provide temporary support during fabrication and are later removed to release the desired structures. This suspended cantilever beam offers versatility in actuation mechanisms, including thermal, electrostatic, piezoelectric, electrothermal, and electromagnetic methods. Electrothermal actuation as described herein harnesses thermal expansion of MEMS cantilevers.

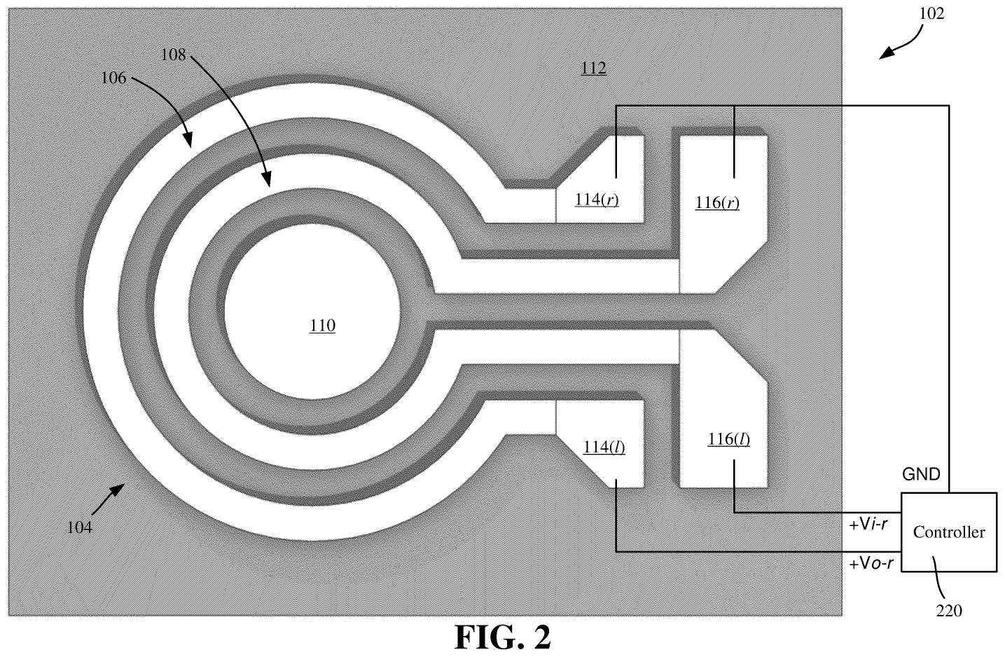

FIG. 2 is a top view representation of the dual-ring dual ring MEMS unit cell of FIG. 1, in which some of the components in FIG. 1 are identically labeled in FIG. 2. FIG. 2 also shows a controller 220 that among other operations, can selectively apply one voltage bias (Vo-r) to one side of the outer ring 106 to heat the outer ring 106, and another voltage (Vi-r) to one side of the inner ring 108 to heat the inner ring 108.

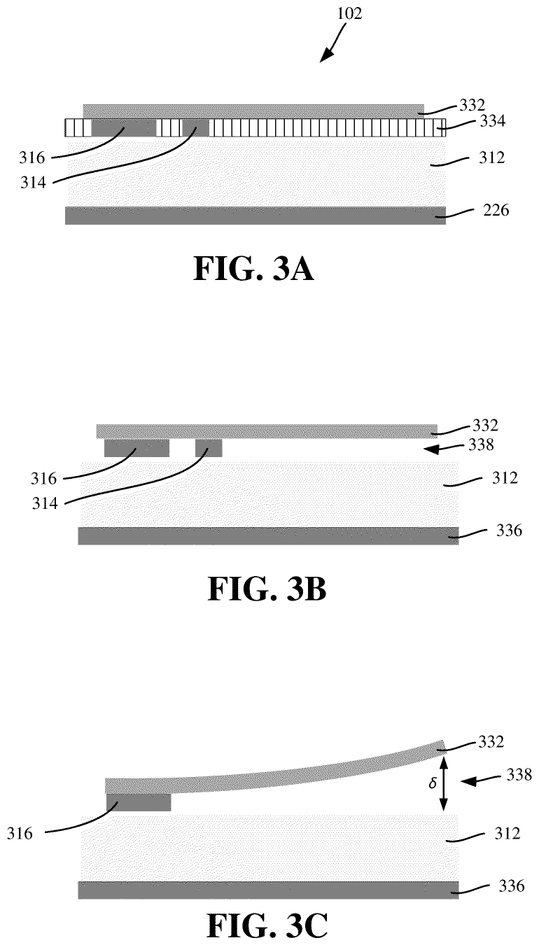

In one nonlimiting implementation, the metallic pattern 104 (FIG. 3) is made from a thin layer of aluminum (Al), which is the top layer 332, as shown in the fabrication cross-section in FIG. 3A. This facilitates efficient fabrication, as all metallic pattern layers can be the same materials, and/or the same thicknesses. In the layer stack of FIG. 3A, going from top to bottom, the top aluminum layer 332 is on the top of a sacrificial layer 334 of silicon dioxide (SiO₂), which sits on a silicon (Si) substrate 312. The anchor layer 314, at the same level as the sacrificial layer 324, can be aluminum or other suitable material. The bottom surface of the substrate 312 is coated with a thin metal (such as aluminum or some other metal like copper) 336, e.g., to serve as the ground plane.

Note that while aluminum is used herein in the examples, any suitable material can be used. In the examples herein, using purely CMOS compatible processes and materials, the reconfigurable intelligent surface patterns are made of aluminum layers.

The sacrificial layer 324 is selectively removed from underneath the outer ring (e.g., 106 in FIG. 1, layer 332 in FIG. 3A), resulting in a cantilever by leaving an air gap 338 on one side of the cantilever/aluminum layer 332 after release as shown in FIG. 3B. The other side of the aluminum layer 332 remains attached to the substrate 312 via the anchors 316 on one end. It is understood that although only one cantilever is depicted in FIG. 3B (and FIG. 3C), dual cantilevers are present, that is, as described with reference to FIG. 1, the outer moveable ring 104 (with anchor 314 visible in FIGS. 3A and 3B) and the inner moveable ring 108 is formed during the same process.

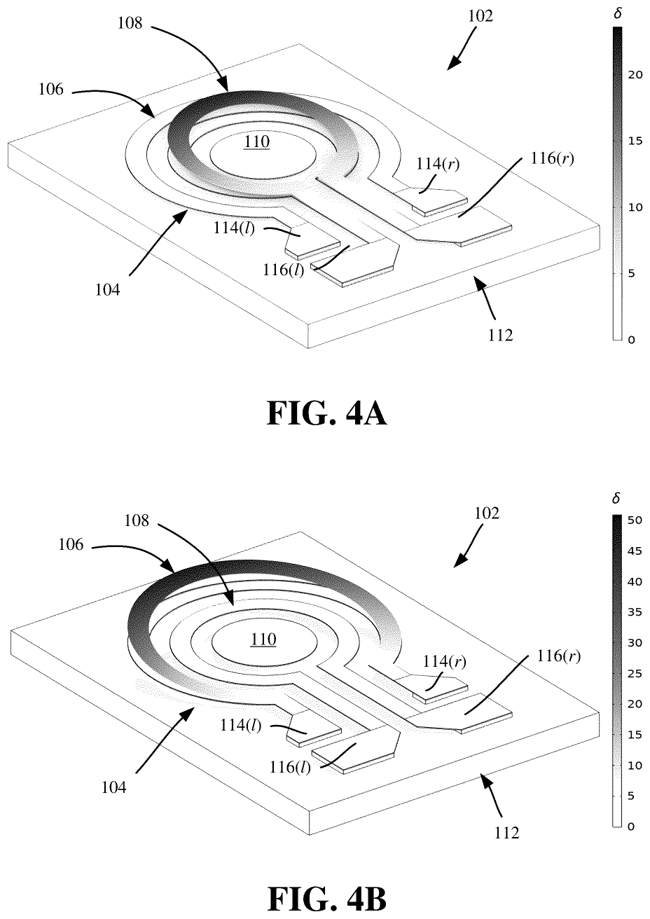

As will be understood, joule heating results in electrothermal actuation, such as to curve the heated aluminum layer 332 upward based on the amount of joule heating, as generally represented in FIG. 3C. Note that the vertical displacement δ increases, as apparent from the larger air gap 338 in the actuated state shown in FIG. 3C, relative to the non-actuated state in FIG. 3B. The other anchor 314 and its cantilever are intentionally omitted from FIG. 3C to emphasize the bend; one or both cantilevers may be bent as described with reference to FIGS. 4A-7D. Although not explicitly shown, it is feasible to have a metallic ring that bends downward in response to joule heating, e.g., in an alternative implementation, the cantilever can be angled somewhat upward when non-actuated, and bent downward when subject to joule heating, which also will change the unit cell geometry.

FIG. 3C thus corresponds to a unit cell in the actuated state, which shows the vertical displacement, δ, of the tip of one cantilever type ring under electrothermal actuation due to thermal expansion from applied voltage/joule heating without any other external forces applied. The vertical displacement δ can be derived from the thermal expansion equation and the bending moment equation:

$$δ = αΔ {TD}^{2} \frac{1}{2 R}$$

where α refers to coefficient of thermal expansion (α=23.1×10⁻⁶−K⁻¹ for aluminum), ΔT is the change in temperature due to Joule heating, D is the outside diameter of the displacement ring, and R is the radius of curvature of the bent cantilever due to thermal expansion. Note that this is a simplified expression that does not consider the width of the ring and Young's modulus, which brings bending stiffness of the ring into picture. Incorporating these factors into the above equation makes it significantly more complex and often requires numerical methods for precise solutions.

To summarize, material such as aluminum atop a silicon (Si) substrate, is initially supported by a sacrificial layer of silicon dioxide. A subsequent fabrication step involves selectively etching away the sacrificial layer beneath the inner middle ring (while not fully etching away the disk, if not otherwise anchored, so that the disk remains fixed to the substrate). This makes one portion of each ring hang above the substrate, with the other portion physically coupled to the substrate at two fixed anchors, which also can act as bias pads. This structure acts somewhat similar to a MEMS cantilever design. A voltage difference applied across one of these anchor pairs causes joule heating effect in the corresponding thin floating metal ring, resulting in out-of-plane displacement or curved motion of the that ring's free end.

One or both rings may be heated for controlled displacement. As shown in the 3D perspective representations of FIGS. 4A and 4B, only one ring may be heated at a time. In the example of FIG. 4A, when a voltage difference is applied across the anchor pads 116(l) and 116(r), e.g., as controlled by the controller 220 (FIG. 2), the resulting current through the metal inner ring 108 causes the joule heating effect, resulting in out-of-plane displacement δ or curved motion of the inner ring's free end; (no units are given for δ, as the overall size of the unit cell factor into the amount of displacement δ, however in general the displacement is at a millimeter (mm) level). At the same time in this example, when no voltage difference is applied across the anchor pads 114(l) and 114(r), e.g., as also controlled by the controller 220 (FIG. 2), there is no joule heating of the outer ring 106, whereby the outer ring 106 remains in its flat, non-actuated state.

Conversely, in the example of FIG. 4B, when a voltage difference is applied across the anchor pads 114(l) and 114(r), e.g., as controlled by the controller 220 (FIG. 2), the resulting current through the metal outer ring 106 causes the joule heating effect, resulting in out-of-plane displacement or curved motion of the outer ring's free end. At the same time in this example, when no voltage difference is applied across the anchor pads 116(l) and 116(r), e.g., as also controlled by the controller 220 (FIG. 2), there is no joule heating of the inner ring 108, whereby the inner ring 108 remains in its flat, non-actuated state.

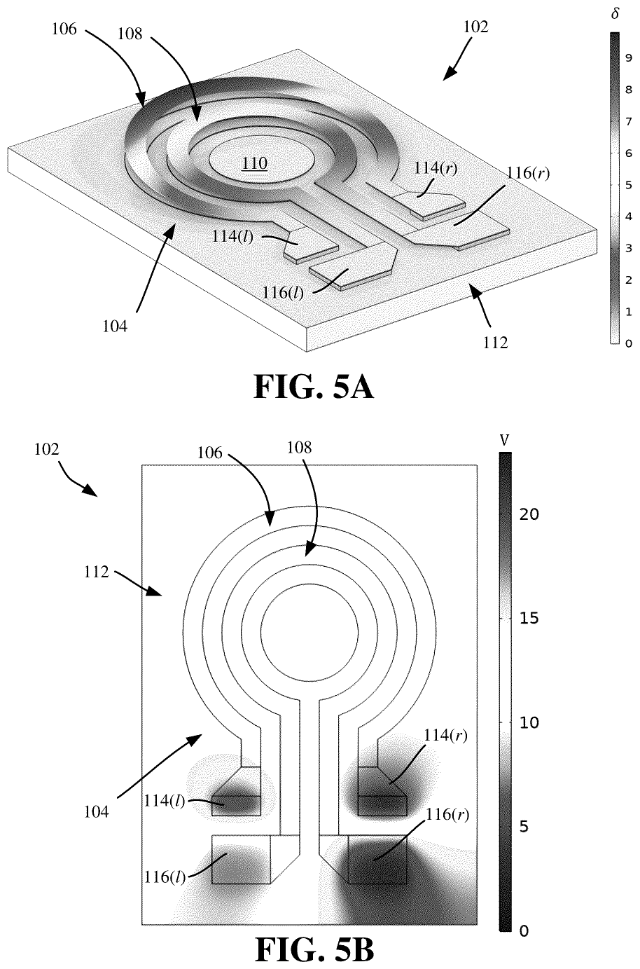

FIG. 5A shows a 3D perspective representation when both the inner and outer ring are heated. More particularly, when a first voltage difference is applied across the anchor pads 114(l) and 114(r), e.g., as controlled by the controller 220 (FIG. 2), the resulting current through the metal outer ring 106 causes the joule heating effect, resulting in out-of-plane displacement or curved motion of the outer ring's free end. At the same time in this example, when a second voltage difference is applied across the anchor pads 116(l) and 116(r), e.g., as controlled by the controller 220 (FIG. 2), the resulting current through the metal inner ring 108 causes the joule heating effect, resulting in out-of-plane displacement or curved motion of the inner ring's free end. The suspended structures (the non-anchored portions of the cantilevers) bend upwards with increasing temperature, that is, the deformations in the actuated states causes the rings 106 and 108 to curve upward relative to their non-actuated states.

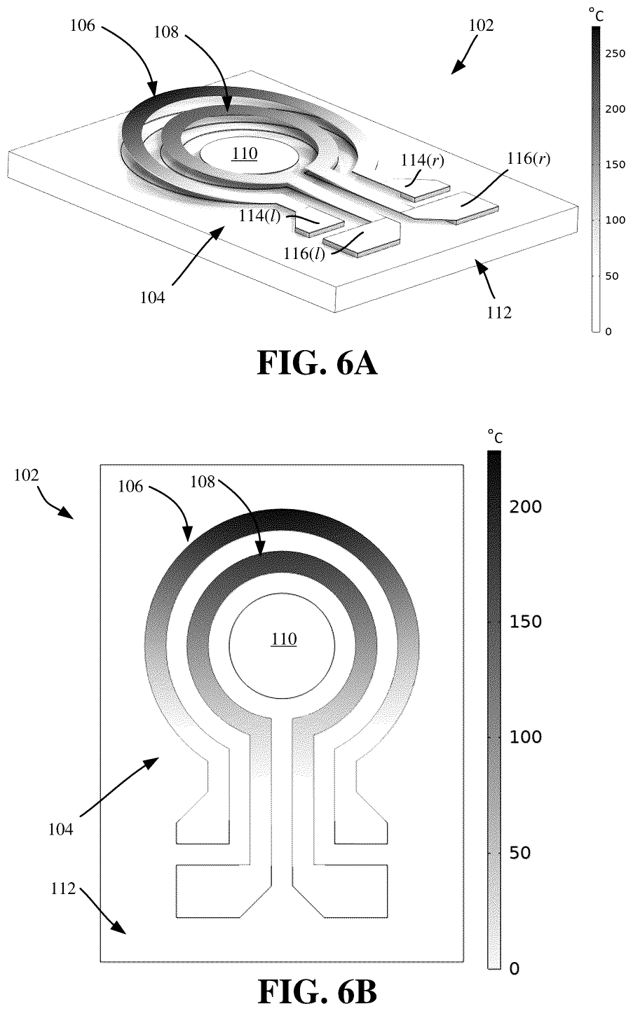

FIG. 5B is a top view that shows the corresponding voltage distribution. FIGS. 6A and 6B are 3D perspective views when both the inner and outer ring are heated, showing example temperatures. Because of size differences, the inner ring may not need the same amount of voltage and/or heating to cause full deformation as the outer ring needs. Note that partial deformation of one ring, with full or no deformation of the other ring is feasible, as is full deformation of one ring, with full or no deformation of the other ring. In general, this structural deformation under the effect of temperature caused by electrical voltage can be referred to as electrothermal actuation.

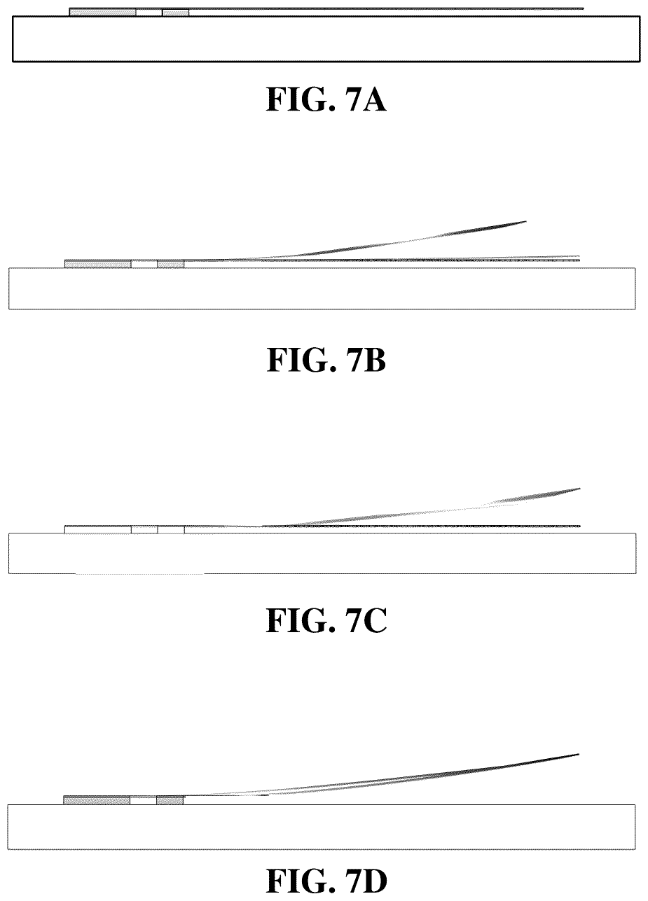

FIG. 7A-7D show front/side views of the dual ring unit cell. FIG. 7A shows the unit cell with neither cantilever actuated. FIG. 7B shows the unit cell with the inner ring cantilever actuated, e.g., corresponding to FIG. 4A. FIG. 7C shows the unit cell with the outer ring cantilever actuated, e.g., corresponding to FIG. 4B. FIG. 7D shows the unit cell with both cantilevers actuated, e.g., corresponding to FIGS. 5A, 5B, 6A and 6B.

Temperature driven expansion of the metal layer results in an overall out-of-plane deformation of one or both of the cantilevers. Hence, the actuation method is electrothermal, which offers larger stroke and higher repeatability. Multicycle operation of electrothermally reconfigurable MEMS RIS is achieved using such thin metal cantilevers.

To summarize, when electrical voltage is applied to the anchor pads of a ring-type cantilever, the temperature of the heated ring increases due to joule heating. This causes the aluminum to bend, that is, the suspended portion of the ring bends upwards away from the substrate with increasing temperature, such that the vertical displacement δ is increased based on the applied voltage. This continuous structural deformation drives a shift in the resonance frequency of the unit cell towards higher frequencies. Consequently, an incident electromagnetic wave reflects off the two-dimensional array of such reconfigurable intelligent surface unit cells, exhibiting varying phase values determined by the structural displacement in each cell. These individually controllable phase values can thus be used for constructive/destructive interference to beamform the reflected electromagnetic wave.

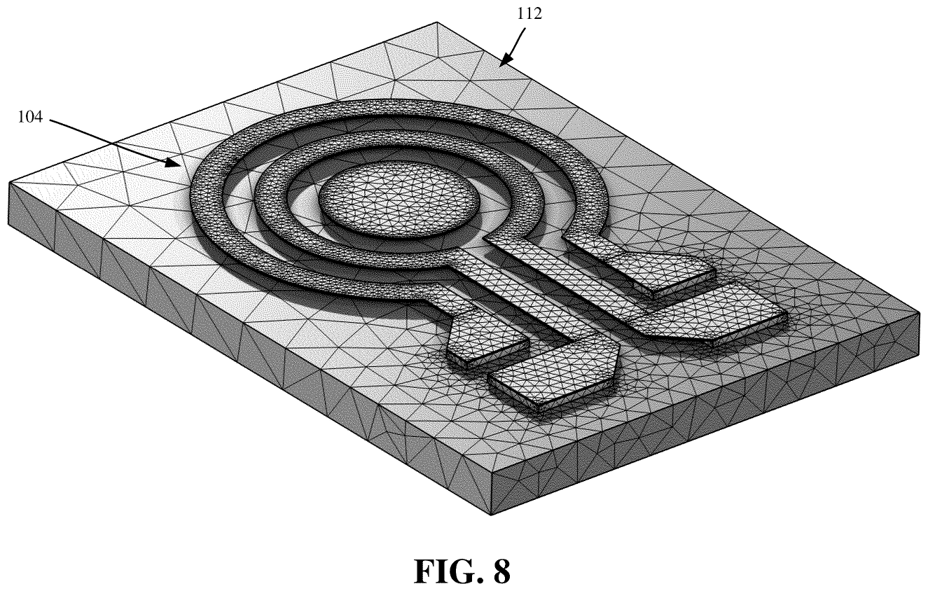

Turning to an analysis, a finite element analysis tool (e.g., COMSOL MULTIPHYSICS) can be used; note that the interactions between thermal expansion, material stiffness, and geometric dimensions lead to nonlinear effects that are not easily captured in a closed-form equation. In general, finite element analysis involves dividing a continuous domain into smaller, simpler elements, referred to as the meshing as shown in FIG. 8. Finite element analysis solves partial differential equations, which are discretized over the elements of the mesh to approximate the behavior of the system; (note that without meshing, it would be highly impractical to solve these equations numerically). The finer the mesh, the more accurate the response generated, e.g., the substrate 112 has a coarse mesh, whereas the elements of the resonating pattern 104 have a finer mash.

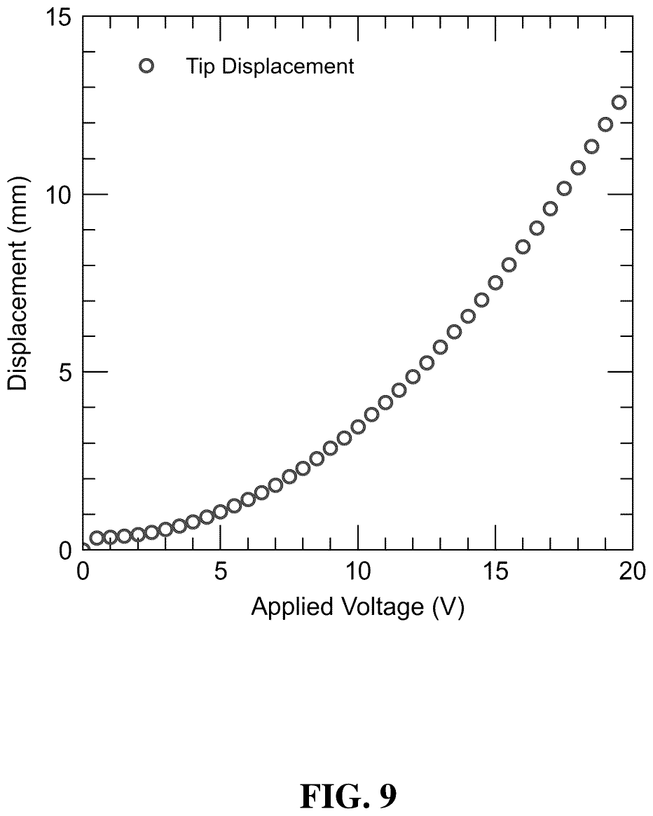

To evaluate the displacement of one example ring that acts like a cantilever, voltage differences from 0 V to 20 V are applied on the anchors starting from 0 V up to 20 V in incremental steps of 1 V. FIG. 9 shows the voltage difference in a simulation setup, in units of millimeters of displacement δ. When electrical current passes through the thin aluminum ring, the temperature of the entire reconfigurable intelligent surface unit cell increases due to joule heating as described herein. This rise in temperature leads to the upward deformation of ring. Note that the maximum voltage that is applied (e.g., FIG. 5B) corresponds to a maximum joule heating temperature (e.g., FIG. 5A) that is far less than the melting point of aluminum of 660 degrees Celsius (° C.).

As the voltage is decreased (the device starts to cool down), the ring starts coming back downwards, highlighting the repeatability of the operation. The curve in FIG. 9 shows the normalized displacement at the tip of the ring achieved with the applied voltage. The curve in FIG. 9 shows the displacement at the tip of the ring achieved with the applied voltage. It is observed that for an applied voltage of 20 V, the corresponding displacement (e.g., of 13 mm in one implementation, although different implementations will have different dimensions) is attained, which is very large and can provide good tunability in the resonance frequency of the structure.

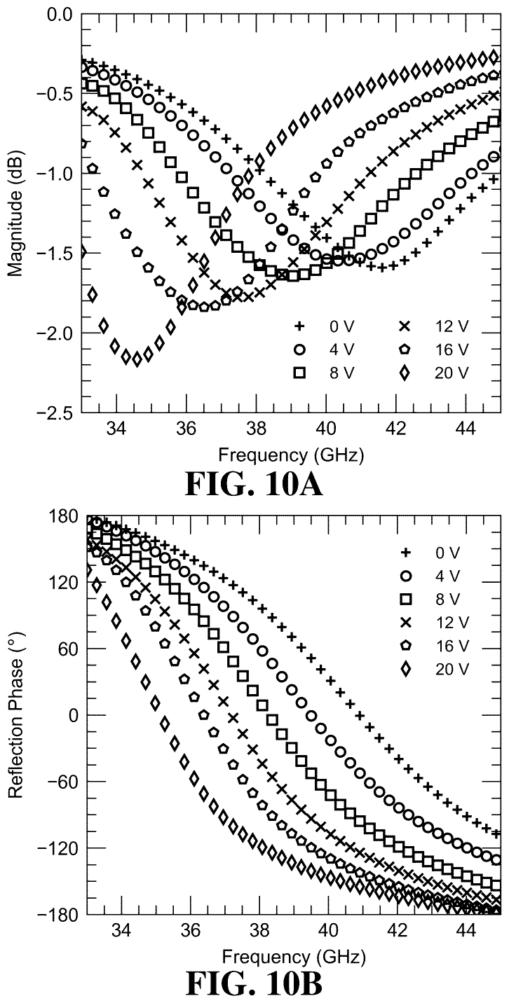

Full wave analysis can be done in 3D electromagnetic simulation software (e.g., Ansys HFSS) to extract the reflection characteristics of the unit cell for the tuning range. Periodic boundary conditions can be used during simulation of the cell, which assume an infinite structure. A parametric simulation can be done for different displacement levels of the ring cantilever by adjusting the applied voltage. The resonance frequency is at 37 GHz when the ring is suspended after the sacrificial layer etching; this non-actuated state corresponds to a voltage supply of 0 V. Continuous tuning is observed in the resonant frequency with respect to the input voltage. When the voltage is 20 V, the resonant frequency is at 45 GHz as shown in FIGS. 10A and 10B.

The reason for this phenomenon is that the resonant frequency of the reconfigurable intelligent surface structure can be given as:

$$ω = \sqrt{\frac{1}{LC}} ,$$

where L and C refer to the effective inductance and capacitance in the reconfigurable intelligent surface structure that enables coupling of the incident electromagnetic wave. It can be quantitatively seen that as the ring bends away from the substrate, the gap between the metal and the substrate increases. This decreases the capacitance, whereby the resonance frequency increases. Compared to an electrostatic actuation mechanism, a larger range of motion can be achieved by using electrothermal actuation, which causes a larger shift in the resonance frequency and the corresponding output phase.

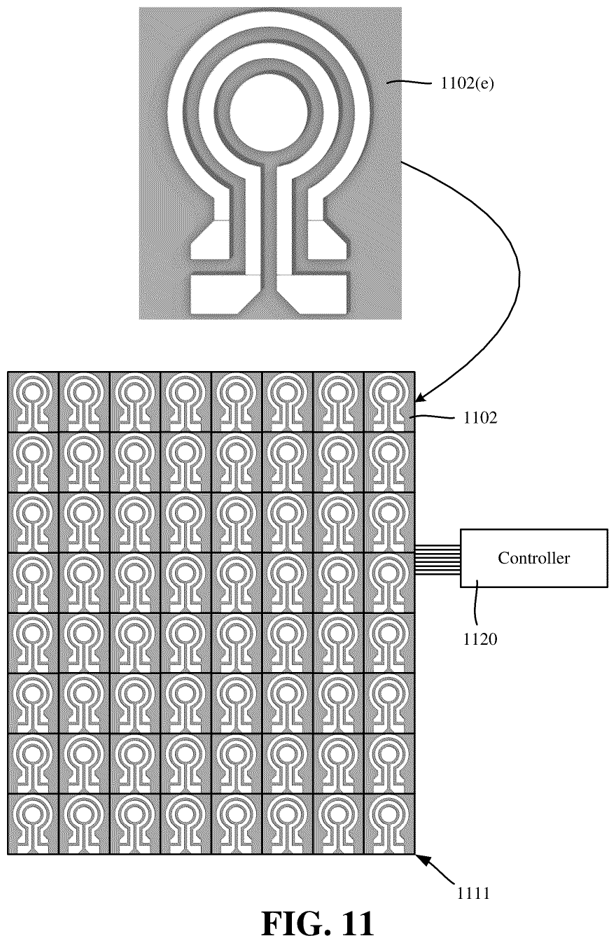

FIG. 11 shows a reconfigurable intelligent surface 1111 that is a made of an array of unit cells; one such unit cell 1102 is labeled; (an enlarged view of the unit cell 1102(e) is also depicted. The controller 1120 can selectively heat the inner ring and the outer ring. Note that in contrast to a single ring design, a dual ring is able to provide an extended phase tuning range. For example, the controller can apply one voltage to displace the inner ring to its maximum displacement, and the phase tuning range can be extended by applying another voltage for displacing the outer ring, e.g., up to some percentage (e.g., thirty percent) more displacement.

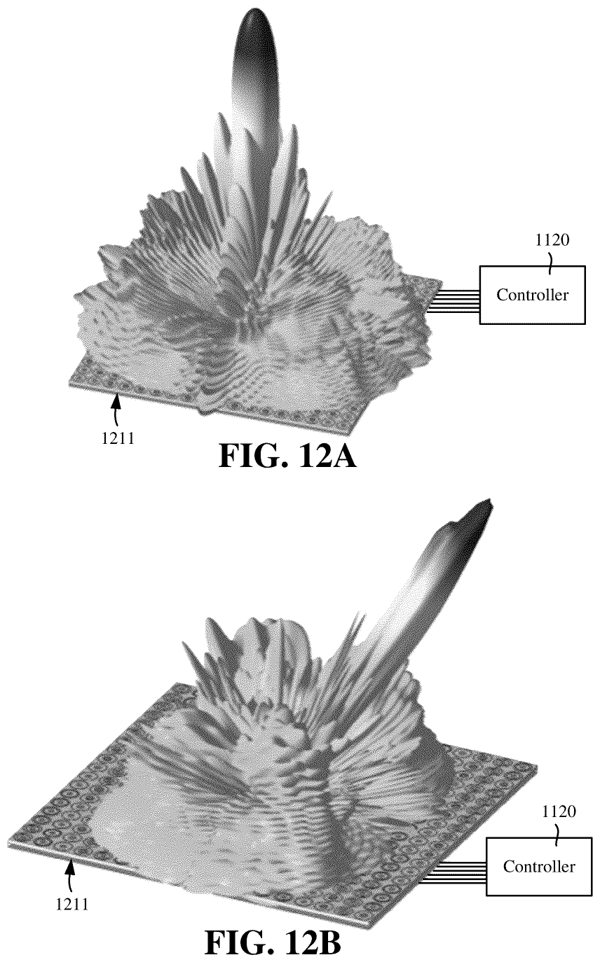

This change in phase from individual unit cell leads to constructive/destructive interference in the desired direction when combined into an array to form a reconfigurable intelligent surface panel. Such beam steering is shown in FIGS. 12A and 12B in which the reflected beam can be steered in a desired direction based on the voltages applied to the cantilever rings of the unit cells. More particularly, for redirecting impinging signals, the reconfigurable intelligent surface 1211 is coupled to or otherwise incorporates the controller 1120 that controls the phase shifts of the unit cells designed for signal redirection by applying appropriate voltages (e.g., from zero volts to the maximum voltage) to the unit cells to deform respective inner and/or outer rings to change their respective phases, facilitating constructive (or destructive interference) for beamforming. Beamforming allows the incoming electromagnetic wave/signal to be redirected (reflected or refracted) as a beam that can be shaped and steered in a desired direction, as shown in FIG. 12A (one set of respective voltages for the respective unit cells), and 12B (another set of respective voltages for the respective unit cells).

To summarize, the dual cantilever MEMS-based actuator for a reconfigurable unit cell offers a higher tuning range, larger stroke, and enhanced repeatability compared to other unit cell technologies, achieving a large maximum tuning range via the dual rings. This electrothermal approach is particularly effective for applications needing substantial displacements and force outputs at the millimeter/microscale device level.

One or more example embodiments can be embodied in a unit cell device, such as described and represented herein. The unit cell device can include a microelectromechanical systems (MEMS)-based resonating pattern on a substrate, which can include a fixed resonating portion, and a metallic MEMS dual cantilever. The metallic MEMS dual cantilever can include a first cantilever part; the first cantilever part can include a first anchored portion and a first non-anchored portion, and the first cantilever part can have a first vertical displacement distance relative to the substrate at a first tip of the first non-anchored portion, in response to the first non-anchored portion being in a first non-actuated state. The metallic MEMS dual cantilever further can include a second cantilever part; the second cantilever part can include a second anchored portion and a second non-anchored portion, and the second cantilever part can have a second vertical displacement distance relative to the substrate at a second tip of the second non-anchored portion as a result of second residual stress, in response to the second non-anchored portion being in a second non-actuated state. The unit cell device can include first electrical contact pads electrically coupled to the first cantilever part, in which first energy applied via the first electrical contact pads changes the first non-actuated state of the first cantilever part to a first actuated state that bends the first cantilever part from the first vertical displacement distance at the first tip to a third vertical displacement distance that can be based on a first amount of the first energy applied. The unit cell device further can include second electrical contact pads electrically coupled to the second cantilever part, in which second energy applied via the second electrical contact pads changes the second non-actuated state of the second cantilever part to a second actuated state that bends the second cantilever part from the second vertical displacement distance at the second tip to a fourth vertical displacement distance that can be based on a second amount of the second energy applied. In response to an impinging electromagnetic wave on the unit cell device, the resonating pattern resonates to redirect an instance of the electromagnetic based on a phase shift determined by the first vertical displacement distance in response to the first cantilever part being in the first non-actuated state, or the third vertical displacement distance in response to the first cantilever part being in the first actuated state, and the second vertical displacement distance in response to the second cantilever part being in the second non-actuated state, or the fourth vertical displacement distance in response to the second cantilever part being in the second actuated state.

In the first non-actuated state, the first cantilever part is substantially unbent and is substantially parallel to the substrate, and in the actuated state, the metallic cantilever bends upward relative to the substrate, and wherein the first vertical displacement distance is less than the third vertical displacement distance, relative to the substrate.

In the non-actuated state, the first cantilever part is substantially unbent, and in the actuated state, the first cantilever part bends downward relative to the substrate, and wherein the first vertical displacement distance is greater than the third vertical displacement distance.

The first energy applied via the first electrical contact pads can include a first bias voltage applied across the first electrical contact pads, and the first amount of the first energy applied can be based on a bias voltage level.

The phase shift can be a first phase shift corresponding to the first energy applied via the first electrical contact pads and the second energy applied via the second electrical contact pads, and third energy applied via the first electrical contact pads and fourth energy applied via the second electrical contact pads can determine a second phase shift of the unit cell device that can be different from the first phase shift.

The metallic MEMS dual cantilever can include aluminum.

The fixed resonating portion can include a fixed disk physically coupled to the substrate, the first cantilever part can include an outer penannular ring, and the second cantilever part can include an inner penannular ring between the outer penannular ring and the fixed disk. A first gap of the outer penannular ring can be formed by first parallel sides that extend from the outer penannular ring and can be physically coupled to first opposite sides of the first anchored portion proximate to the first contact pads, and a second gap of the inner penannular ring can be formed by second parallel sides that extend from the inner penannular ring and can be physically coupled to second opposite sides of the second anchored portion proximate to the second contact pads.

The redirected instance can be a first redirected instance, the unit cell device can be part of a reconfigurable intelligent surface that can include the unit cell device and other unit cell devices arranged in an array that forms the reconfigurable intelligent surface, and the phase shift of the unit cell device can redirect the first redirected instance of the electromagnetic wave in a direction that can create constructive interference with a second redirected instance of the electromagnetic wave as redirected from at least one other of the other unit cell devices.

The fixed resonating portion and the metallic MEMS dual cantilever can be fabricated above a sacrificial layer; the sacrificial layer can be partially removed by sacrificial layer etching with respect to the fixed resonating portion, resulting in the fixed resonating portion being physically coupled to the substrate, and the sacrificial layer can be fully removed with respect to the first non-anchored portion of the first cantilever part of the metallic MEMS dual cantilever, resulting in a first air gap between the first non-anchored portion and the substrate; the sacrificial layer can be fully removed with respect to the second non-anchored portion of the second cantilever part of the metallic MEMS dual cantilever, resulting in a second air gap between the second non-anchored portion and the substrate.

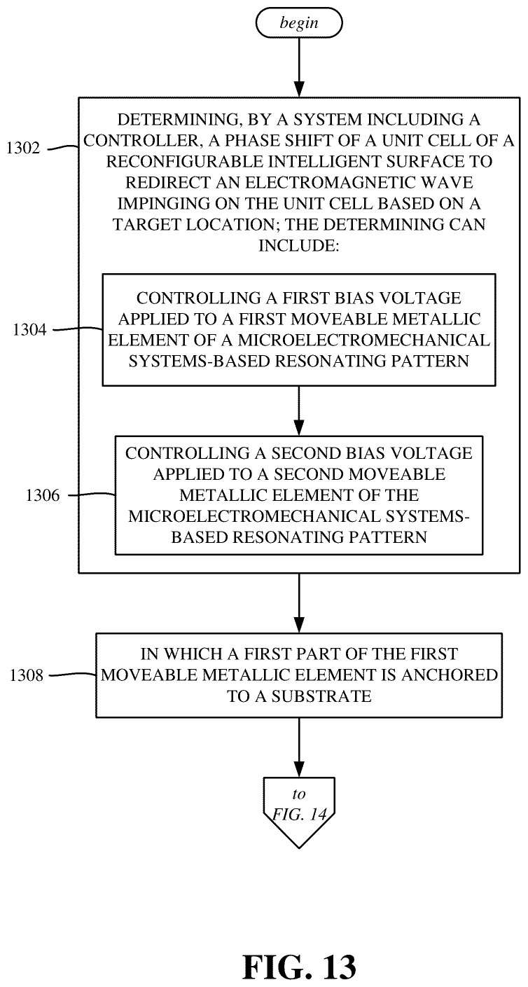

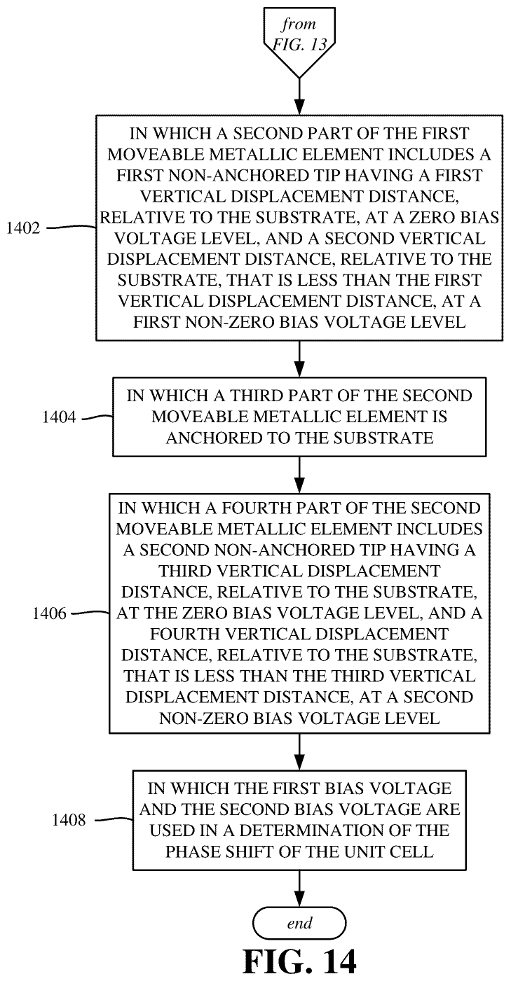

One or more example aspects, such as corresponding to example operations of a method, or a system/a machine-readable medium having executable instructions that, when executed by a controller, facilitate performance of the operations, are represented in FIGS. 13 and 14. Example operation 1302 represents determining, by a system including a controller, a phase shift of a unit cell of a reconfigurable intelligent surface to redirect an electromagnetic wave impinging on the unit cell based on a target location, The determining can include example operations 1304 and 1306. Example operation 1304 represents controlling a first bias voltage applied to a first moveable metallic element of a microelectromechanical systems-based resonating pattern. Example operation 1306 represents controlling a second bias voltage applied to a second moveable metallic element of the microelectromechanical systems-based resonating pattern. Example block 1308 represents a first part of the first moveable metallic element being anchored to a substrate. Example block 1402 of FIG. 14 represents a second part of the first moveable metallic element, which can include a first non-anchored tip having a first vertical displacement distance, relative to the substrate, at a zero bias voltage level, and a second vertical displacement distance, relative to the substrate, that is less than the first vertical displacement distance, at a first non-zero bias voltage level. Example block 1404 represents a third part of the second moveable metallic element anchored to the substrate. Example block 1406 represents a fourth part of the second moveable metallic element, which can include a second non-anchored tip having a third vertical displacement distance, relative to the substrate, at the zero bias voltage level, and a fourth vertical displacement distance, relative to the substrate, that is less than the third vertical displacement distance, at a second non-zero bias voltage level. Example block 1408 represents the first bias voltage and the second bias voltage being used in a determination of the phase shift of the unit cell.

The phase shift can be a first phase shift, the target location is a first target location, and further operations can include obtaining, by the system, information representative of a second target location, and in response to the obtaining of the information, redirecting, by the system, the electromagnetic wave based on the second location, which can include changing the first bias voltage from the first bias voltage to a third bias voltage, and changing the second bias voltage from the first bias voltage to a fourth bias voltage, to change the first phase shift to a second phase shift that is different from the first phase shift.

The unit cell can be part of a reconfigurable intelligent surface that can include the unit cell and other unit cells arranged in an array that forms the reconfigurable intelligent surface; changing the phase shift of the unit cell based on the target location can redirect the electromagnetic wave to create constructive interference with the electromagnetic wave as redirected from at least one of the other unit cells, with respect to beamforming the electromagnetic wave as redirected towards the target location.

The unit cell can be part of a reconfigurable intelligent surface that can include the unit cell and other unit cells arranged in an array that forms the reconfigurable intelligent surface; changing the phase shift of the unit cell based on the target location can create destructive interference with the electromagnetic wave as redirected from at least one of the other unit cells.

One or more example embodiments can be embodied in a system, such as described and represented herein. The system can include a unit cell configured to redirect an incoming electromagnetic wave as a redirected electromagnetic wave. The unit cell can include a substrate, and a resonating pattern corresponding to the incoming electromagnetic wave. The resonating pattern can include a fixed metallic resonator, and a first metallic cantilever that can include a first anchored portion physically coupled to the substrate, and a first non-anchored portion physically decoupled from the substrate. The first metallic cantilever can be curved upward with a first larger amount of curvature, when heated by a first non-zero amount of joule heating, relative to a first lesser amount of curvature, when not heated by joule heating; a first resultant amount of curvature can correspond to the first non-zero amount of joule heating. The resonating pattern further can include a second metallic cantilever that can include a second anchored portion physically coupled to the substrate, and a second non-anchored portion physically decoupled from the substrate. The second metallic cantilever can be curved upward with a second larger amount of curvature, when heated by a second non-zero amount of joule heating, relative to a second lesser amount of curvature, when not heated by joule heating; a second resultant amount of curvature can correspond to the second non-zero amount of joule heating. The unit cell can include first electrical contacts coupled to the first metallic cantilever proximate to the first anchored portion, second electrical contacts coupled to the second metallic cantilever proximate to the second anchored portion, and a controller. The controller can be configured to selectively apply energy to the first electrical contacts and the second electrical contacts to selectively heat at least one of: the first metallic cantilever with a first selected amount of joule heating, corresponding to a first selected amount of curvature of the first metallic cantilever, or the second metallic cantilever with a second selected amount of joule heating, corresponding to a second selected amount of curvature of the second metallic cantilever. The first selected amount of curvature and the second selected amount of curvature can determine a direction of the redirected electromagnetic wave.

The first anchored portion of the first metallic cantilever can be physically coupled to the substrate by respective first anchors, and the respective first anchors can be electrically coupled to respective first electrical contacts of the first electrical contacts.

The controller can apply at least one of: a first selected bias voltage or current to the first electrical contacts to heat the first metallic cantilever with the first selected amount of joule heating, or a second selected bias voltage or current to the second electrical contacts to heat the second metallic cantilever with the second selected amount of joule heating.

At least one of: the first metallic cantilever can include aluminum, or the second metallic cantilever can include aluminum.

The fixed resonating portion can include a fixed disk physically coupled to the substrate, the first metallic cantilever can include an outer penannular ring, and the second metallic cantilever can include an inner penannular ring positioned between the outer penannular ring and the fixed disk.

The unit cell can be a first unit cell of a reconfigurable intelligent surface that can include the first unit cell and a second unit cell, the first selected amount of joule heating can be a first selected amount, the second selected amount of joule heating can be a second selected amount, the redirected electromagnetic wave can be a first redirected electromagnetic wave, the direction of the first redirected electromagnetic wave can be a first direction, and to create constructive interference of the first redirected electromagnetic wave as redirected from the first unit cell in the first direction, with a second redirected electromagnetic wave as redirected from the second unit cell in a second direction, the controller can select the first selected amount of joule heating and the second selected amount of joule heating for the first unit cell, and select a third selected amount of joule heating for the second unit cell and select a fourth selected amount of joule heating for the second unit cell.

As can be seen, the technology described herein is directed to a reconfigurable intelligent surface that integrates MEMS micro-actuators within the reconfigurable intelligent surface's unit cells, facilitating dynamic reshaping of unit cell geometries without the need for PIN diodes/varactors. By combining MEMS and reconfigurable intelligent surface technologies as described herein, the example unit cells designs facilitate MEMS integration with a reconfigurable intelligent surface that overcomes many current limitations in reconfigurable intelligent surface technologies, facilitating advanced wireless communication solutions. By seamlessly integrating MEMS with reconfigurable intelligent surface designs, e.g., during the fabrication process, active tuning capabilities result from the integration of bias networks, without the need for on-chip soldering of components and hence eliminating any intricate wiring complexities.

In one implementation, each reconfigurable intelligent surface unit cell includes a distinctive metallic pattern resembling a bullseye, characterized by a central disk encircled by two concentric rings. The inner ring is anchored at one portion and free at the opposite portion, resulting in a first cantilever that is vertically deformed by first joule heating. The outer ring is similarly anchored at one portion and free at the opposite portion, resulting in a second cantilever that is vertically deformed by second joule heating. Control of the amount of vertical displacement of each cantilever via a continuously tunable millimeter-wave unit cell can be accomplished by selectively applying respective analog voltages to heat the respective rings. Consequently, an incident electromagnetic wave reflects off the two-dimensional array of such unit cells in a controlled direction based on the varying phase values determined by the structural displacement in each cell.

The above description of illustrated embodiments of the subject disclosure, comprising what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

As used in this application, the terms “component,” “system,” “platform,” “layer,” “selector,” “interface,” and the like are intended to refer to a computer-related resource or an entity related to an operational apparatus with one or more specific functionalities, wherein the entity can be either hardware, a combination of hardware and software, software, or software in execution. As an example, a component can be an apparatus with specific functionality provided by mechanical parts operated by electric or electronic circuitry. As yet another example, a component can be an apparatus that provides specific functionality through electronic components without mechanical parts, the electronic components can comprise a processor therein to execute software or firmware that confers at least in part the functionality of the electronic components.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances.

While the embodiments are susceptible to various modifications and alternative constructions, certain illustrated implementations thereof are shown in the drawings and have been described above in detail. It should be understood, however, that there is no intention to limit the various embodiments to the specific forms disclosed, but on the contrary, the intention is to cover all modifications, alternative constructions, and equivalents falling within the spirit and scope.

In addition to the various implementations described herein, it is to be understood that other similar implementations can be used or modifications and additions can be made to the described implementation(s) for performing the same or equivalent function of the corresponding implementation(s) without deviating therefrom. Still further, multiple processing chips or multiple devices can share the performance of one or more functions described herein, and similarly, storage can be effected across a plurality of devices. Accordingly, the various embodiments are not to be limited to any single implementation, but rather are to be construed in breadth, spirit and scope in accordance with the appended claims.

What is claimed is:

1. A unit cell device, comprising:
a microelectromechanical systems (MEMS)-based resonating pattern on a substrate, comprising:
a fixed resonating portion;
a metallic MEMS dual cantilever comprising:
a first cantilever part, the first cantilever part comprising a first anchored portion and a first non-anchored portion, the first cantilever part having a first vertical displacement distance relative to the substrate at a first tip of the first non-anchored portion, in response to the first non-anchored portion being in a first non-actuated state, and
a second cantilever part, the second cantilever part comprising a second anchored portion and a second non-anchored portion, the second cantilever part having a second vertical displacement distance relative to the substrate at a second tip of the second non-anchored portion, in response to the second non-anchored portion being in a second non-actuated state;
first electrical contact pads electrically coupled to the first cantilever part, wherein first energy applied via the first electrical contact pads changes the first non-actuated state of the first cantilever part to a first actuated state that bends the first cantilever part from the first vertical displacement distance at the first tip to a third vertical displacement distance that is based on a first amount of the first energy applied; and
second electrical contact pads electrically coupled to the second cantilever part, wherein second energy applied via the second electrical contact pads changes the second non-actuated state of the second cantilever part to a second actuated state that bends the second cantilever part from the second vertical displacement distance at the second tip to a fourth vertical displacement distance that is based on a second amount of the second energy applied,
wherein, in response to an impinging electromagnetic wave on the unit cell device, the resonating pattern resonates to redirect an instance of the electromagnetic based on a phase shift determined by:
the first vertical displacement distance in response to the first cantilever part being in the first non-actuated state, or the third vertical displacement distance in response to the first cantilever part being in the first actuated state; and
the second vertical displacement distance in response to the second cantilever part being in the second non-actuated state, or the fourth vertical displacement distance in response to the second cantilever part being in the second actuated state.

2. The unit cell device of claim 1, wherein, in the first non-actuated state, the first cantilever part is substantially unbent and is substantially parallel to the substrate, and in the actuated state, the metallic cantilever bends upward relative to the substrate, and wherein the first vertical displacement distance is less than the third vertical displacement distance, relative to the substrate.

3. The unit cell device of claim 1, wherein, in the non-actuated state, the first cantilever part is substantially unbent, and in the actuated state, the first cantilever part bends downward relative to the substrate, and wherein the first vertical displacement distance is greater than the third vertical displacement distance.

4. The unit cell device of claim 1, wherein the first energy applied via the first electrical contact pads comprises a first bias voltage applied across the first electrical contact pads, and wherein the first amount of the first energy applied is based on a bias voltage level.

5. The unit cell device of claim 1, wherein the phase shift is a first phase shift corresponding to the first energy applied via the first electrical contact pads and the second energy applied via the second electrical contact pads, and wherein third energy applied via the first electrical contact pads and fourth energy applied via the second electrical contact pads determine a second phase shift of the unit cell device that is different from the first phase shift.

6. The unit cell device of claim 1, wherein the metallic MEMS dual cantilever comprises aluminum.

7. The unit cell device of claim 1, wherein the fixed resonating portion comprises a fixed disk physically coupled to the substrate, wherein the first cantilever part comprises an outer penannular ring, and wherein the second cantilever part comprises an inner penannular ring between the outer penannular ring and the fixed disk.

8. The unit cell device of claim 7, wherein a first gap of the outer penannular ring is formed by first parallel sides that extend from the outer penannular ring and are physically coupled to first opposite sides of the first anchored portion proximate to the first contact pads, and wherein a second gap of the inner penannular ring is formed by second parallel sides that extend from the inner penannular ring and are physically coupled to second opposite sides of the second anchored portion proximate to the second contact pads.

9. The unit cell device of claim 1, wherein the redirected instance is a first redirected instance, wherein the unit cell device is part of a reconfigurable intelligent surface comprising the unit cell device and other unit cell devices arranged in an array that forms the reconfigurable intelligent surface, and wherein the phase shift of the unit cell device redirects the first redirected instance of the electromagnetic wave in a direction that creates constructive interference with a second redirected instance of the electromagnetic wave as redirected from at least one other of the other unit cell devices.

10. The unit cell device of claim 1, wherein the fixed resonating portion and the metallic MEMS dual cantilever are fabricated above a sacrificial layer, wherein the sacrificial layer is partially removed by sacrificial layer etching with respect to the fixed resonating portion, resulting in the fixed resonating portion being physically coupled to the substrate, wherein the sacrificial layer is fully removed with respect to the first non-anchored portion of the first cantilever part of the metallic MEMS dual cantilever, resulting in a first air gap between the first non-anchored portion and the substrate, and wherein the sacrificial layer is fully removed with respect to the second non-anchored portion of the second cantilever part of the metallic MEMS dual cantilever, resulting in a second air gap between the second non-anchored portion and the substrate.

11. A method, comprising,
determining, by a system comprising a controller, a phase shift of a unit cell of a reconfigurable intelligent surface to redirect an electromagnetic wave impinging on the unit cell based on a target location, the determining comprising:
controlling a first bias voltage applied to a first moveable metallic element of a microelectromechanical systems-based resonating pattern, and
controlling a second bias voltage applied to a second moveable metallic element of the microelectromechanical systems-based resonating pattern;
wherein a first part of the first moveable metallic element is anchored to a substrate,
wherein a second part of the first moveable metallic element comprises a first non-anchored tip having a first vertical displacement distance, relative to the substrate, at a zero bias voltage level, and a second vertical displacement distance, relative to the substrate, that is less than the first vertical displacement distance, at a first non-zero bias voltage level,
wherein a third part of the second moveable metallic element is anchored to the substrate,
wherein a fourth part of the second moveable metallic element comprises a second non-anchored tip having a third vertical displacement distance, relative to the substrate, at the zero bias voltage level, and a fourth vertical displacement distance, relative to the substrate, that is less than the third vertical displacement distance, at a second non-zero bias voltage level, and
wherein the first bias voltage and the second bias voltage are used in a determination of the phase shift of the unit cell.

12. The method of claim 11, wherein the phase shift is a first phase shift, wherein the target location is a first target location, and further comprising:
obtaining, by the system, information representative of a second target location; and
in response to the obtaining of the information, redirecting, by the system, the electromagnetic wave based on the second location, comprising changing the first bias voltage from the first bias voltage to a third bias voltage, and changing the second bias voltage from the first bias voltage to a fourth bias voltage, to change the first phase shift to a second phase shift that is different from the first phase shift.

13. The method of claim 11, wherein the unit cell is part of a reconfigurable intelligent surface comprising the unit cell and other unit cells arranged in an array that forms the reconfigurable intelligent surface, and wherein the changing of the phase shift of the unit cell based on the target location redirects the electromagnetic wave to create constructive interference with the electromagnetic wave as redirected from at least one of the other unit cells, with respect to beamforming the electromagnetic wave as redirected towards the target location.

14. The method of claim 11, wherein the unit cell is part of a reconfigurable intelligent surface comprising the unit cell and other unit cells arranged in an array that forms the reconfigurable intelligent surface, and wherein the changing of the phase shift of the unit cell based on the target location creates destructive interference with the electromagnetic wave as redirected from at least one of the other unit cells.

15. A system, comprising:
a unit cell configured to redirect an incoming electromagnetic wave as a redirected electromagnetic wave, the unit cell comprising:
a substrate;
a resonating pattern corresponding to the incoming electromagnetic wave, the resonating pattern comprising:
a fixed metallic resonator;
a first metallic cantilever comprising a first anchored portion physically coupled to the substrate, and a first non-anchored portion physically decoupled from the substrate, the first metallic cantilever being curved upward with a first larger amount of curvature, when heated by a first non-zero amount of joule heating, relative to a first lesser amount of curvature, when not heated by joule heating, wherein a first resultant amount of curvature corresponds to the first non-zero amount of joule heating;
a second metallic cantilever comprising a second anchored portion physically coupled to the substrate, and a second non-anchored portion physically decoupled from the substrate, the second metallic cantilever being curved upward with a second larger amount of curvature, when heated by a second non-zero amount of joule heating, relative to a second lesser amount of curvature, when not heated by joule heating, wherein a second resultant amount of curvature corresponds to the second non-zero amount of joule heating;
first electrical contacts coupled to the first metallic cantilever proximate to the first anchored portion;
second electrical contacts coupled to the second metallic cantilever proximate to the second anchored portion; and
a controller configured to selectively apply energy to the first electrical contacts and the second electrical contacts to selectively heat at least one of: the first metallic cantilever with a first selected amount of joule heating, corresponding to a first selected amount of curvature of the first metallic cantilever, or the second metallic cantilever with a second selected amount of joule heating, corresponding to a second selected amount of curvature of the second metallic cantilever,
wherein the first selected amount of curvature and the second selected amount of curvature determine a direction of the redirected electromagnetic wave.

16. The system of claim 15, wherein the first anchored portion of the first metallic cantilever is physically coupled to the substrate by respective first anchors, and wherein the respective first anchors are electrically coupled to respective first electrical contacts of the first electrical contacts.

17. The system of claim 15, wherein the controller applies at least one of: a first selected bias voltage or current to the first electrical contacts to heat the first metallic cantilever with the first selected amount of joule heating, or a second selected bias voltage or current to the second electrical contacts to heat the second metallic cantilever with the second selected amount of joule heating.

18. The system of claim 15, wherein at least one of: the first metallic cantilever comprises aluminum, or the second metallic cantilever comprises aluminum.

19. The system of claim 15, wherein the fixed resonating portion comprises a fixed disk physically coupled to the substrate, wherein the first metallic cantilever comprises an outer penannular ring, and wherein the second metallic cantilever comprises an inner penannular ring positioned between the outer penannular ring and the fixed disk.

20. The system of claim 15, wherein the unit cell is a first unit cell of a reconfigurable intelligent surface comprising the first unit cell and a second unit cell, wherein the first selected amount of joule heating is a first selected amount, wherein the second selected amount of joule heating is a second selected amount, wherein the redirected electromagnetic wave is a first redirected electromagnetic wave, wherein the direction of the first redirected electromagnetic wave is a first direction, and
wherein to create constructive interference of the first redirected electromagnetic wave as redirected from the first unit cell in the first direction, with a second redirected electromagnetic wave as redirected from the second unit cell in a second direction, the controller:
selects the first selected amount of joule heating and the second selected amount of joule heating for the first unit cell, and
selects a third selected amount of joule heating for the second unit cell and selects a fourth selected amount of joule heating for the second unit cell.
